(19) United States
(12) Patent Application Publication
(10) Pub. No.: US 2011/0286271 A1
(43) Pub. Date: Nov. 24, 2011

(54) MEMORY SYSTEMS AND METHODS FOR READING DATA STORED IN A MEMORY CELL OF A MEMORY DEVICE

(75) Inventor: Hong-Ching Chen, Kao-Hsiung Hsien (TW)

(73) Assignee: MEDIATEK INC., Hsin-Chu (TW)

(21) Appl. No.: 12/784,621

(22) Filed: May 21, 2010

(51) Int. Cl. G11C 16/06; G11C 16/04

(52) U.S. Cl. 365/185.09; 365/185.18; 365/185.2

(57) ABSTRACT

A memory system is provided. A memory device includes multiple memory cells for storing data. A controller is coupled to the memory device for accessing the memory device. When reading the data stored in a memory cell, the controller receives a digital signal representing content of the data stored in the memory cell, and detects a level of a voltage or conducted current of the memory cell according to the digital signal to obtain the content of the data.

### BACKGROUND OF THE INVENTION

1. Field of the Invention

The invention relates to a method and memory system for reading data stored in a memory cell of a memory device.

2. Description of the Related Art

Flash memory is widely used in electronic products today, especially for portable applications, as a result of its non-volatility and in system re-programmability. The basic structure of a flash memory cell includes a control gate, a drain diffusion region and a source diffusion region on the substrate. A transistor with a floating gate under the control gate forms an electron storage device. A channel region lies under the floating gate with a tunnel oxide insulation layer between the channel and floating gate. The energy barrier of the tunnel oxide can be overcome by applying a sufficiently high electric field across the tunnel oxide. Thus, electrons passes through the tunnel oxide insulation layer, to change the amount of electrons stored in the floating gate. The amount of electrons stored in the floating gate determines the threshold voltage (Vt) of a cell. The greater the amount of electrons stored in the floating gate, the higher the Vt. The Vt of a cell is used to represent stored data of a cell.

Generally, a flash memory, which can store one bit of data in a cell, is called a Single Level Cell (SLC). Meanwhile, the flash memory, which can store more than one bit of data in a cell, is called a Multiple Level Cell (MLC). Multiple Level Cell (MLC) technology has attracted a lot of research attention due to its area efficiency. By storing 2^{N} discrete levels of Vt, the MLC can store N bits of data per cell, thus reducing the equivalent cell size to 1/N. Because of the advantages of multiple bits of data per cell, the MLC has become one of the best candidates for mass storage applications that typically require greater and greater densities.

### BRIEF SUMMARY OF THE INVENTION

Memory systems and method for reading data stored in a memory cell of a memory device are provided. An embodiment of a memory system comprises a memory device and a controller. The memory device comprises a plurality of memory cells for storing data. A controller is coupled to the memory device to access the memory device. When reading the data stored in a memory cell, the controller receives a digital signal representing content of the data stored in the memory cell, and detects a level of a voltage or conducted current of the memory cell to obtain the content of the data according to the digital signal.

Another embodiment of a memory system comprises a memory device and a controller. The memory device comprises a plurality of memory cells for storing data. When reading the data stored in a memory cell, the memory device detects a voltage or conducted current of the memory cell to be read and generates an analog detected signal to represent the detected voltage or conducted current. The controller comprises a converter, an adaptive level detector and an error correcting code (ECC) engine. The converter receives the analog detected signal from the memory device and converts the analog detected signal to a digital signal. The adaptive level detector detects a level of the voltage or conducted current of the memory cell to be read according to the digital signal to obtain the content of the data. The ECC engine checks the obtained content for errors and when it is determined that an error has occurred, the error in the obtained content is corrected.

Another embodiment of a method for reading data stored in a memory cell of a memory device comprises: measuring time required for discharging a bit-line voltage of the memory cell to be read to a reference voltage to obtain a measurement result; generating an analog detected signal to represent a detected voltage or conducted current of the memory cell to be read according to the measurement result; converting the analog detected signal to a digital signal; and detecting a level of the voltage or conducted current of the memory cell to be read according to the digital signal to obtain content of the data stored in the memory cell.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1A shows a distribution of two states of an SLC NAND flash;

FIG. 1B shows a current-voltage curve of the conducted transistor current I_{DS} with respect to the control voltage V_{G} of the SLC NAND flash;

FIG. 2A shows a distribution of two states of an MLC NAND flash;

FIG. 2B shows a current-voltage curve of the conducted transistor current I_{DS} with respect to the control voltage V_{G} of the SLC NAND flash;

FIG. 3 shows a memory system according to an embodiment of the invention;

FIG. 4 shows a basic structure of a NAND flash according to an embodiment of the invention;

FIG. 5A and FIG. 5B are schematic diagrams showing two different methods for mapping the bits of the MLC memory cells;

FIG. 6 shows an exemplary gray code mapping rule according to an embodiment of the invention;

FIG. 7 shows an exemplary parallel detecting circuit according to an embodiment of the invention;

FIG. 8 shows a schematic block diagram according to a first embodiment of the invention;

FIG. 9 shows a schematic block diagram according to a second embodiment of the invention;

FIG. 10 shows a schematic block diagram of the detecting circuits according to an embodiment of the invention;

FIG. 11A shows a distribution of four states of an MLC NAND flash with a Gray Code mapping;

FIG. 11B shows a current-voltage curve of the conducted transistor current I_{DS} with respect to the control voltage V_{G} of the MLC NAND flash;

FIG. 12 shows an exemplary discharge curve of four states according to an embodiment of the invention;

FIG. 13 shows an exemplary counter value and the latched values for four different states according to an embodiment of the invention;

FIG. 14 shows an exemplary decision threshold table according to an embodiment of the invention;

FIG. 15 shows a method for adaptively generating decision thresholds according to an embodiment of the invention;

FIG. 16 shows an exemplary page data according to the embodiment of the invention;

FIG. 17 shows an exemplary histogram for calculating a distribution of the latched values of a dedicated word line according to an embodiment of the invention;

FIG. 18 shows a method for interleaving the multiple bits of the same MLC memory cell to the different ECC units according to an embodiment of the invention;

FIG. 19 shows a method for interleaving the multiple bits of the same MLC memory cell to the different ECC units according to another embodiment of the invention;

FIG. 20A shows a schematic encoding block diagram applying a BCH code with a Gray Code mapping;

FIG. 20B shows a schematic decoding block diagram applying a BCH code with a Gray Code mapping;

FIG. 21A shows a schematic encoding block diagram applying a BCH code with Trellis Coded Modulation (TCM) according to another embodiment of the invention;

FIG. 21B shows a schematic decoding block diagram applying a BCH code with Trellis Coded Modulation (TCM) according to another embodiment of the invention;

FIG. 22A shows a schematic encoding block diagram applying a Low Density Parity Check code (LDPC code) according to another embodiment of the invention;

FIG. 22B shows a schematic decoding block diagram applying a LDPC code with soft decision according to another embodiment of the invention;

FIG. 23 shows a detecting circuit in the memory device according to another embodiment of the invention; and

FIG. 24 shows a flow chart of a method for reading data stored in a memory cell in a memory device according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

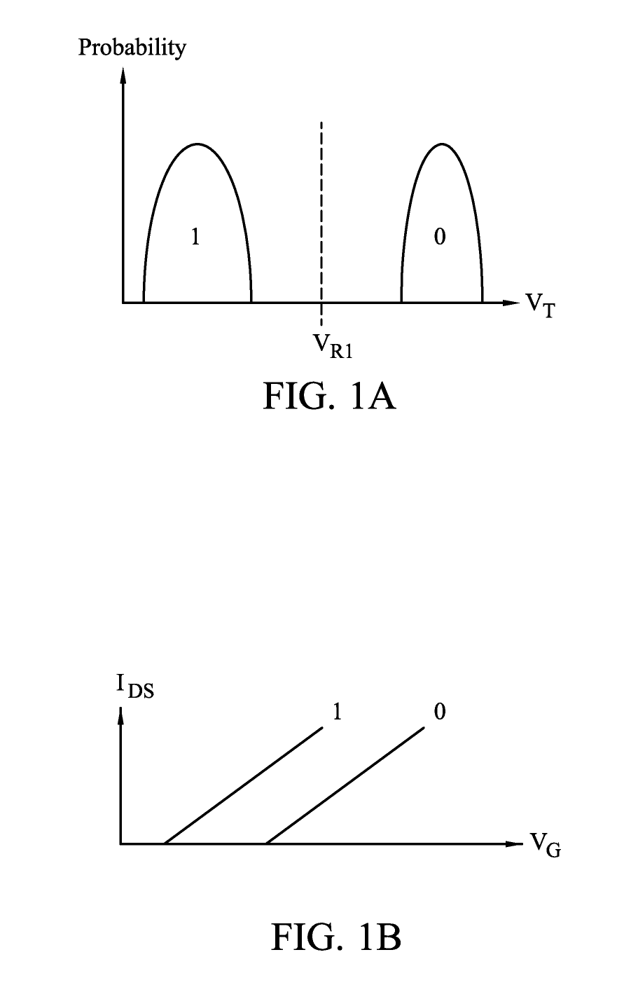

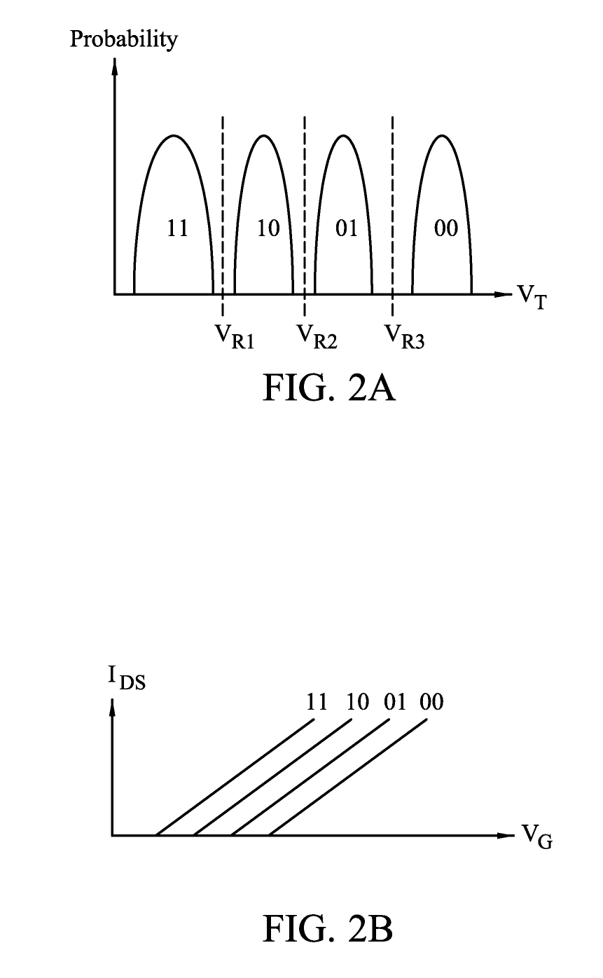

A NAND Flash memory is widely used for storing data in memory cards, USB devices, and Solid State Disks (SSD). A flash memory cell is a transistor with a floating gate (FG). To program a flash memory cell (set to logical 0), the electrons jump onto the floating gate via a process called hot-electron injection. To erase a flash memory cell (set to logical 1), the electrons are pulled from the floating gate by quantum tunneling. The number of elections stored in the floating gate forms the value of the threshold voltage (V_{T}) of a cell transistor, and the stored value is detected by sensing the transistor current (I_{DS}) related to different V_{T}. FIG. 1A shows a distribution of two states (logical 0 and 1) of a Single Level Cell (SLC) NAND flash and FIG. 1B shows a current-voltage (IV) curve of a conducted transistor current I_{DS} with respect to the control voltage V_{G} of the SLC NAND flash. Meanwhile, the Multiple Level Cell (MLC) NAND flash uses multiple levels per cell to store more than a single bit of data. Currently, most MLC NAND flash devices store four logic states per cell as 2 bits of information per cell, reducing cost per bit from previous methods. FIG. 2A shows a distribution of four states (logical 00, 01, 10 and 11) of an MLC NAND flash and FIG. 2B shows a current-voltage (IV) curve of a conducted transistor current I_{DS} with respect to the control voltage V_{G} of the MLC NAND flash.

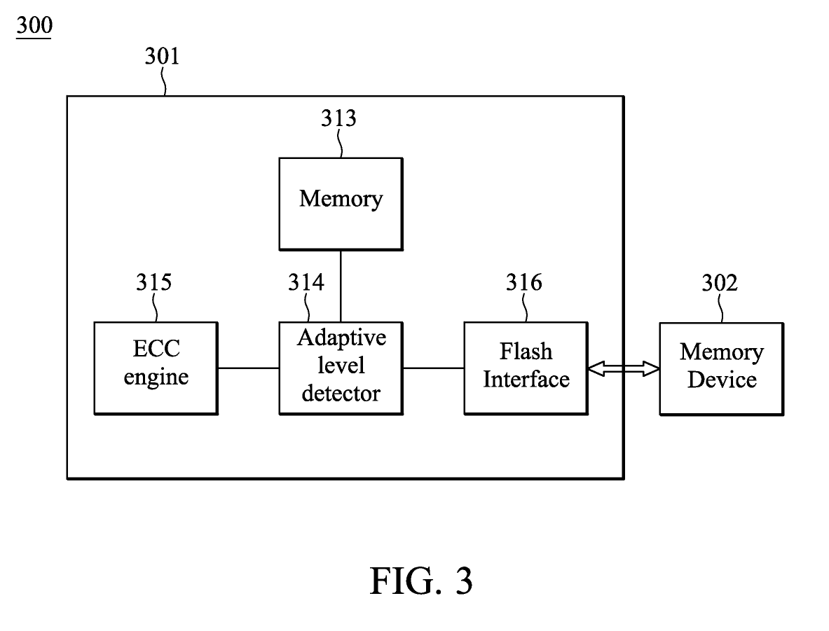

FIG. 3 shows a memory system 300 according to an embodiment of the invention. The memory system 300 comprises a controller 301 and a memory device 302. The memory device 302 may comprise a plurality of memory cells for storing data. According to an embodiment of the invention, the memory device 302 may be a nonvolatile storage device, such as a NAND flash memory. The controller 301 is coupled to the memory device 302 for managing and accessing the memory device 302. The controller 301 comprises a memory 313, an adaptive level detector 314, an Error Correcting Code (ECC) engine 315 and a flash interface 316. The flash interface 316 controls the access operations of the memory device 302. The adaptive level detector 314 detects the data stored in the memory device 302 according to a signal detected from the flash interface 316. The ECC engine 315 provides error correction for the data stored in the memory device 302.

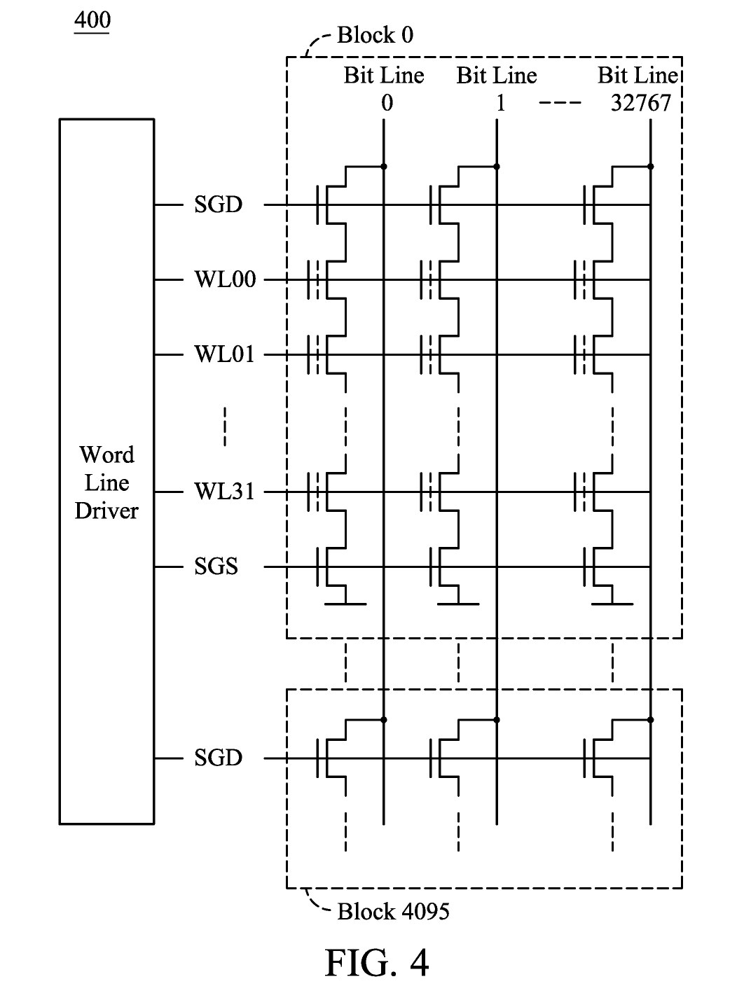

FIG. 4 shows a basic structure of a NAND flash according to an embodiment of the invention. The NAND flash 400 may comprise a plurality of memory blocks (for example, block 0 to block 4095). Each memory block may comprise a plurality of NAND strings with a plurality of word lines (for example, WL00 to WL31). As shown in FIG. 4, each NAND string comprises 32 memory cells coupled in series fashion. The NAND strings with the same bit index in each block are coupled to the same bit line (for example, bit line 0 to bit line 32767).

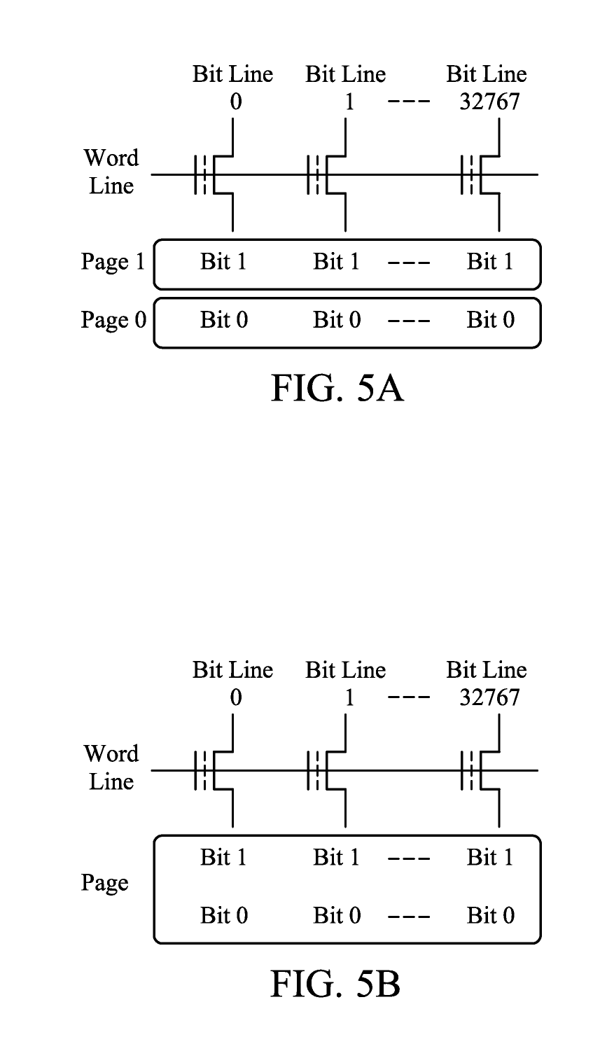

FIG. 5A and FIG. 5B are schematic diagrams showing two different methods for mapping the bits of the MLC memory cells. Take the 2 bits MLC memory cells as an example, as shown in FIG. 5A, the first mapping method interleaves the bits to different pages when data is read or written to the MLC memory cell. Therefore, only one bit may be accessed at a same time. As shown in FIG. 5B, the second mapping method maps all bits of an MLC memory cell to the same page so as multiple bits of the MLC memory cell may be read or written to at the same time. That is, the multiple bits of the MLC memory cell may be simultaneously accessed during an access operation. Generally, the first mapping method is most commonly adopted. However, there are several advantages when using the second mapping method to access multiple bits of the MLC memory cell at the same time, including: (1) increased access throughput and (2) capability to apply channel coding to the bits of the same MLC cell.

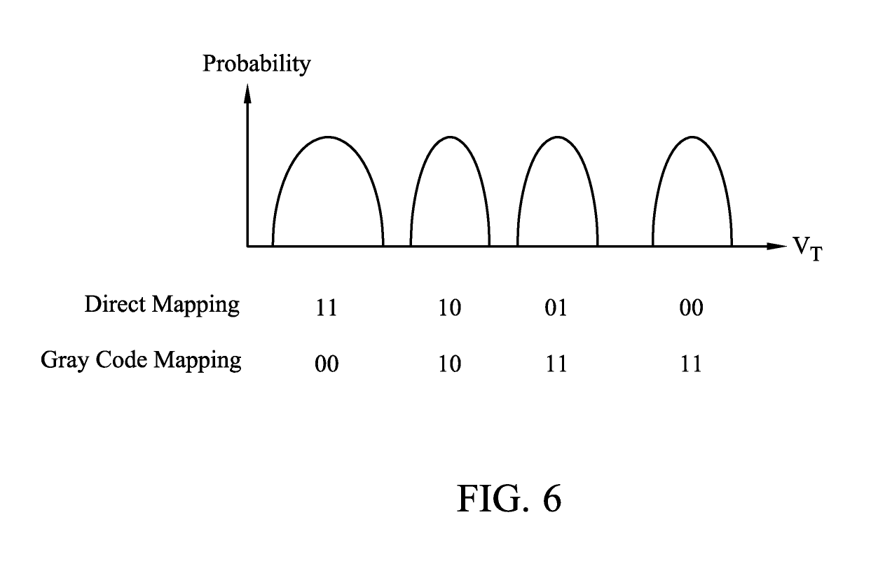

FIG. 6 shows an exemplary gray code mapping rule according to an embodiment of the invention. When an error occurs in the threshold voltage V_{T}, a result of a direct mapping may cause 2 bit errors (10<->01). However, if a gray code mapping is used, a result of the Gray Code mapping may cause only 1 bit error. Therefore, when using the Gray Code mapping, additional coding gain may be obtained with no extra overhead.

However, there are some challenges to accessing multiple bits at the same time. The most important is complexity of the read/write process. For example, there are two methods for reading multiple bits of an MLC memory cell, including a multiple iteration detecting method and a parallel detecting method. The multiple iteration detecting method uses a same sense amplifier to detect one bit during each iteration. Generally, a sense amplifier is coupled to each bit line to detect a threshold voltage of the memory cell. For a 4 bit MLC memory cell, 4 iterations are required. Thus, improvement in access throughput is insignificantly affected. The parallel detecting method uses parallel coupled sense amplifiers and reference cells to detect all bits during one iteration. Thus, improvement in access throughput is significantly affected.

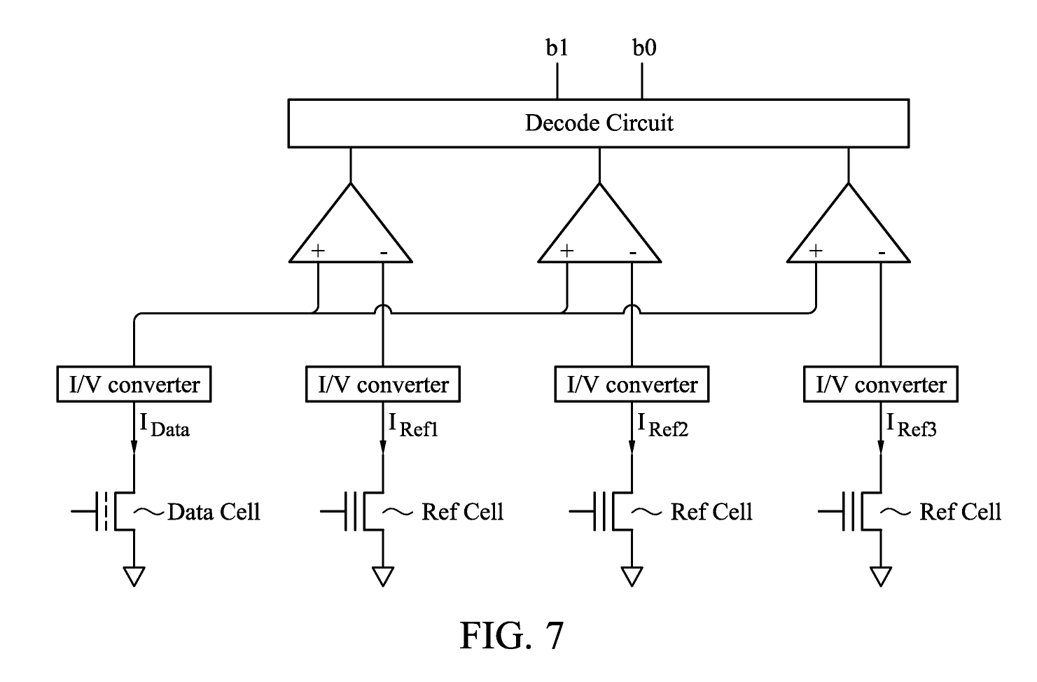

FIG. 7 shows an exemplary parallel detecting circuit according to an embodiment of the invention. In order to detect two bits at one time, three reference cells may be used to provide three different reference currents/voltages and three comparators may be used to compare the conducted current or threshold voltage that has been converted by the IV converter with the reference currents/voltages. However, as shown in FIG. 7, a disadvantage for the parallel detecting method is increased hardware costs and power consumption. For example, when storing more than 2 bits in an MLC memory cell, such as a 3 bit or 4 bit per cell (MLC3X or MLC4X) MLC memory cell, the number of reference voltages for differentiating storage bits are greatly increased, increasing hardware costs and power consumption. In addition, because the distance between each reference voltage level is very narrow due to increasing bit number, the bit error rate is increased. Further, as more powerful error-tolerance and error-correction method is required to diminish the effects of program disturb, read disturb, and interference of neighbor memory cells. Therefore, a novel voltage/current detecting method and ECC structure are highly desired to solve the above-mentioned problems, especially when implementing a multiple bits access technique as shown in FIG. 5B.

According to an embodiment of the invention, when reading the data stored in a memory cell, the detected threshold voltage of the memory cell or current conducted by applying the gate voltage V_{G} to the memory cell may be converted from analog to digital so as to be represented in a digital format. In the embodiments of the invention, the controller may receive a digital signal representing the detected voltage or conducted current of the memory cell. The digital signal carries digital detected result for further decoding and error correction in a digital domain so as to recover the content of data stored in the memory cell. Details of the voltage/current detecting method and ECC structure will be discussed in the following paragraphs.

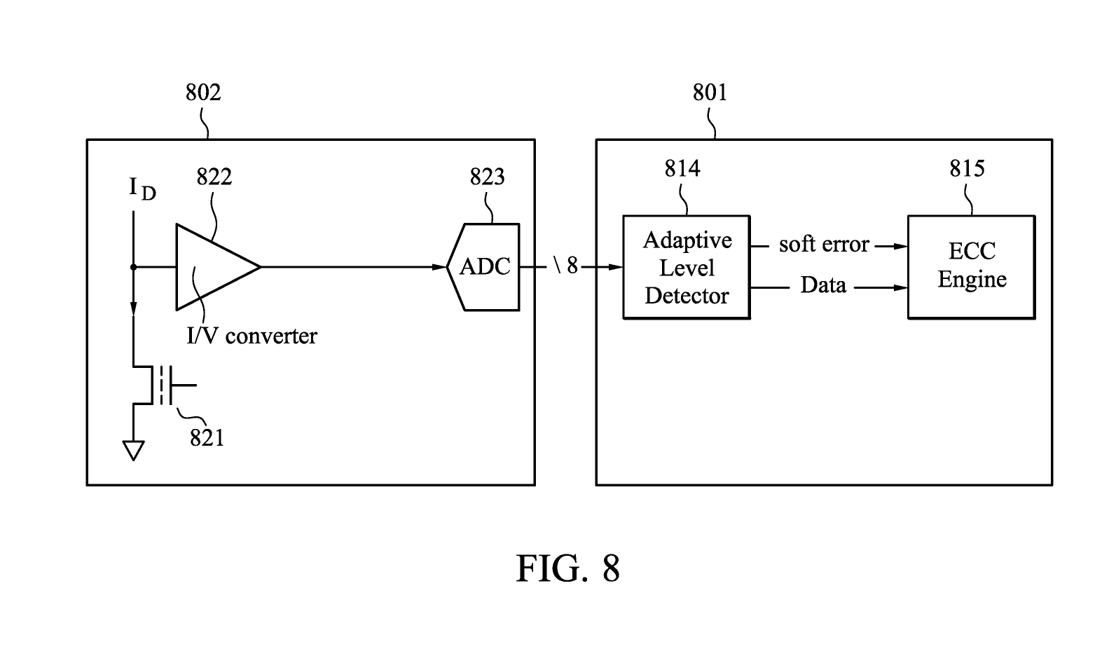

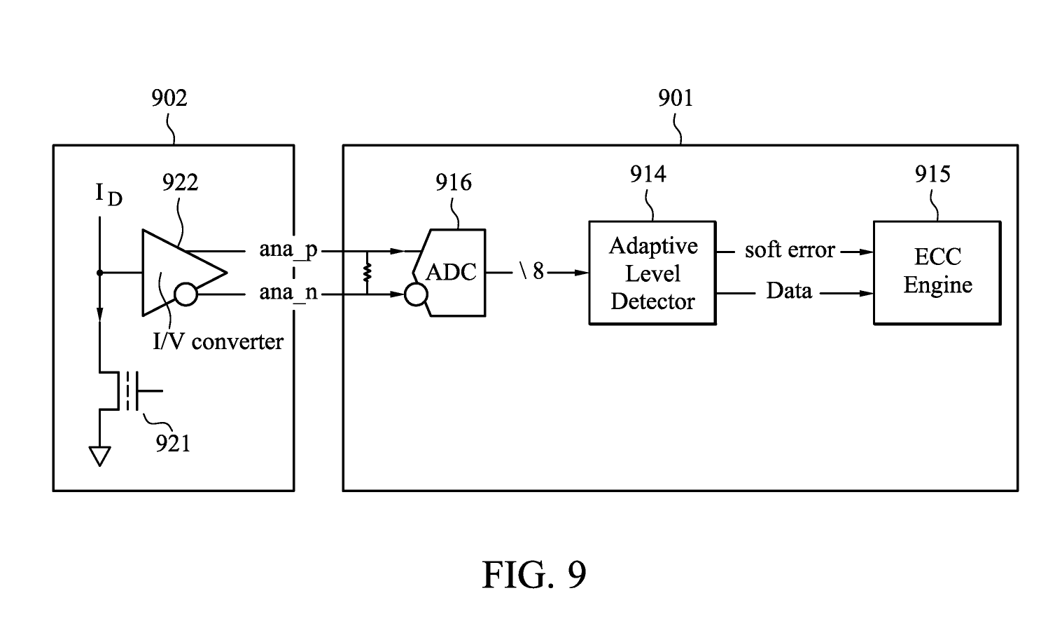

According to a first embodiment of the invention, there is a digital interface between the memory device and the controller. The analog detected voltage or conducted current may be converted to a digital signal by the memory device, and the controller receives the digital detected result carried in the digital signal, detects a level of a voltage or conducted current of the memory cell according to the digital signal to obtain the content of the data. FIG. 8 shows a schematic block diagram according to the first embodiment of the invention. According to the first embodiment, when reading the data stored in a memory cell 821, the memory device 802 may detect the threshold voltage or conducted current I_{D} of the memory cell 821 and generate an analog detected signal to represent the detected voltage or conducted current. Note that there may be several different implementations for detecting the threshold voltage or conducted current I_{D} of the memory cell. As examples, the memory device 802 may directly detect the threshold voltage, or apply a gate voltage to detect the conducted current of the memory cell and thereafter convert the detected current to a corresponding voltage via the current to voltage (I/V) converter 822 as shown in FIG. 8. Therefore, the invention should not be limited thereto. As shown in FIG. 8, the memory device 802 comprises an analog to digital converter (ADC) 823 to convert the analog detected signal to a digital signal. In the embodiments of the invention, the ADC 823 uses 8 bits to represent the digital conversion result. However, the ADC results may also be represented by different number of bits, and the invention should not be limited thereto.

The adaptive level detector 814 of the controller 801 detects a level of a voltage or conducted current of the memory cell according to the digital signal to obtain the content of the data stored in the memory cell. The adaptive level detector 814 passes the obtained content and a soft error (which will be discussed in detail in the following paragraphs) to the ECC engine 815 for correcting the error in the obtained content, when required.

FIG. 9 shows a schematic block diagram according to a second embodiment of the invention. According to the second embodiment of the invention, there is an analog interface between the memory device and the controller. When reading the data stored in a memory cell 921, the memory device 902 may detect the threshold voltage or conducted current I_{D} of the memory cell 921 and generate a pair of analog and differential detected signals ana_p and ana_n to represent the detected voltage or conducted current. The controller 901 receives the pair of analog and differential detected signals ana_p and ana_n. The controller 901 further comprises an ADC 916 to convert the pair of analog and differential detected signals to the digital signal. After receiving the digital signal, the adaptive level detector 914 detects a level of a voltage or conducted current of the memory cell according to the digital signal to obtain the content of the data stored in the memory cell, and passes the obtained content and a soft error to the ECC engine 915 for correcting the error in the obtained content, when required.

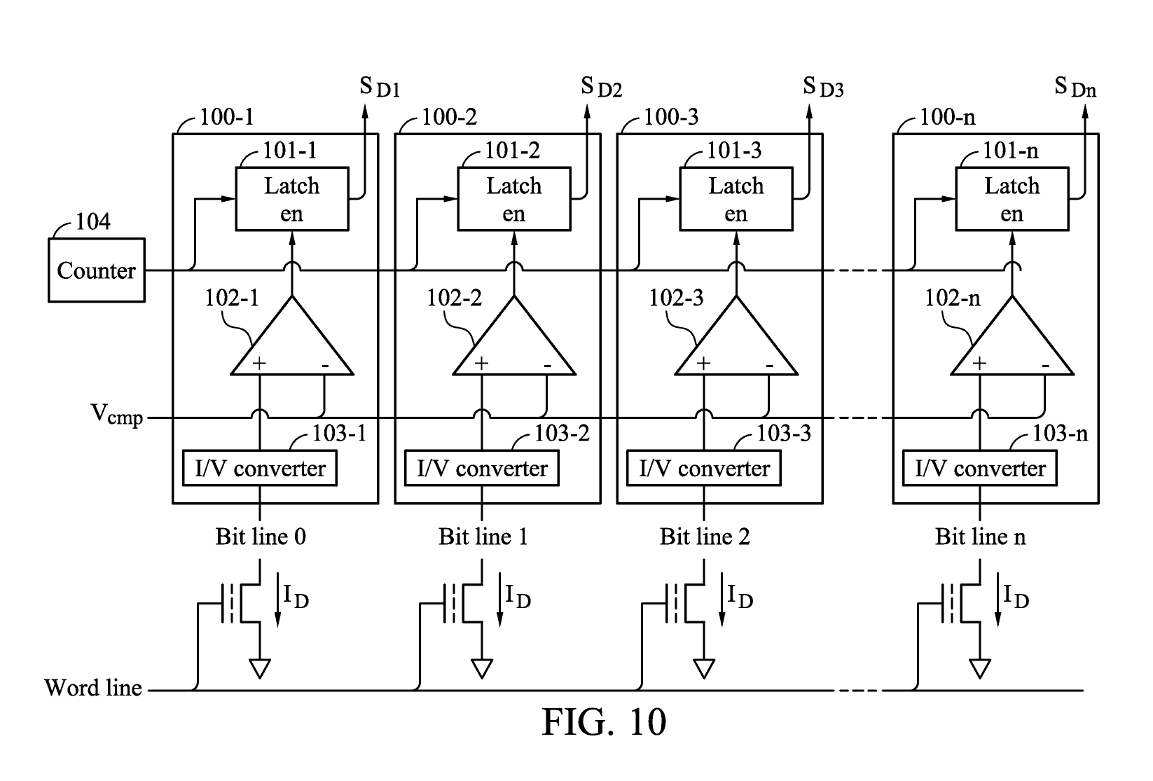

FIG. 10 shows a schematic block diagram of the detecting circuits according to an embodiment of the invention. The detecting circuits 100-1 to 100-n as shown in FIG. 10 may be comprised in the memory device (e.g. 302 or 802) for detecting the voltage or conducted current of the memory cells and generating the digital signal. In the first embodiment of the invention, each of the detecting circuits 100-1 to 100-n is coupled to one of the bit lines (Bit line 0 to Bit line n) for detecting the threshold voltage or conducted current of the memory cells. The memory device may further comprise a counter 104 coupled to the detecting circuits 100-1 to 100-n for counting a value when the controller (e.g. 301 or 801) begins to read the data stored in the memory cells. According to an embodiment of the invention, the counter 104 may be a Gray Code counter so as to further reduce errors occurring in the transition boundary of each counted value. Each of the detecting circuit may comprise a latch, a comparator and a current to voltage converter (I/V) converter. The I/V converters 103-1 to 103-n convert the conducted current I_{D} of each memory cell to a corresponding detected voltage. The comparators 102-1 to 102-n compare the detected voltages of the corresponding memory cells with a reference voltage V_{cmp}. Note that in other embodiments of the invention, the I/V converters may be omitted and the comparators may be the current comparators and the current comparators may directly compare the conducted current of the corresponding memory cells with a reference current, and the invention should not be limited thereto. The latches 101-1 to 101-n are respectively coupled to the counter 104 and the comparators 102-1 to 102-n, receive a comparison result of the corresponding comparator as the latch enable signal ‘en’, and latch a current value counted by the counter when the comparison result indicates that the voltage or conducted current of the memory cell to be read is smaller than the reference voltage or current.

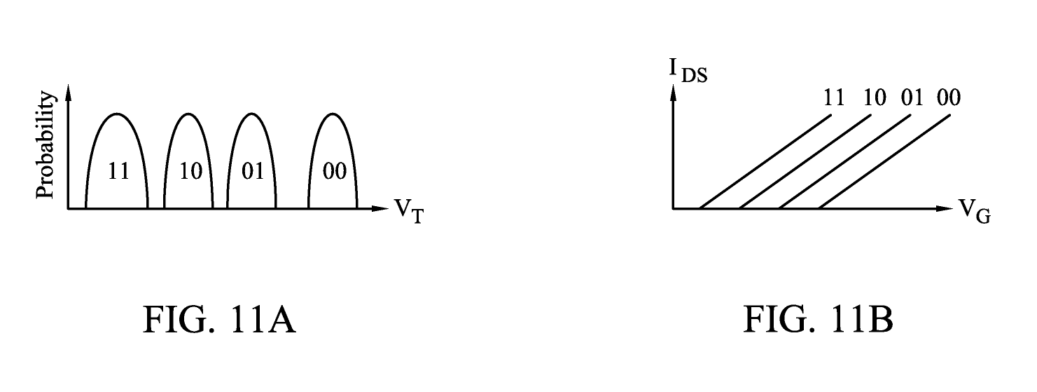

According to the first embodiment of the invention, the charge of the parasitic capacitor in each bit line is discharged by the conducted transistor current I_{DS} of the corresponding memory cell to be read. The detection of the conducted current or voltage is achieved by measuring the time required for discharging the bit-line voltage of the corresponding memory cell to the reference voltage V_{cmp}. If a measured time required for discharging the bit-line voltage of the corresponding memory cell to the reference voltage V_{cmp} is long, then it means that the threshold voltage of the corresponding memory cell is high, or the conducted transistor current I_{DS} is small. FIG. 11A shows a distribution of four states (logical 00, 01, 10 and 11) of an MLC NAND flash and FIG. 11B shows a current-voltage (IV) curve of the conducted transistor current I_{DS} with respect to the control voltage V_{G} of the MLC NAND flash.

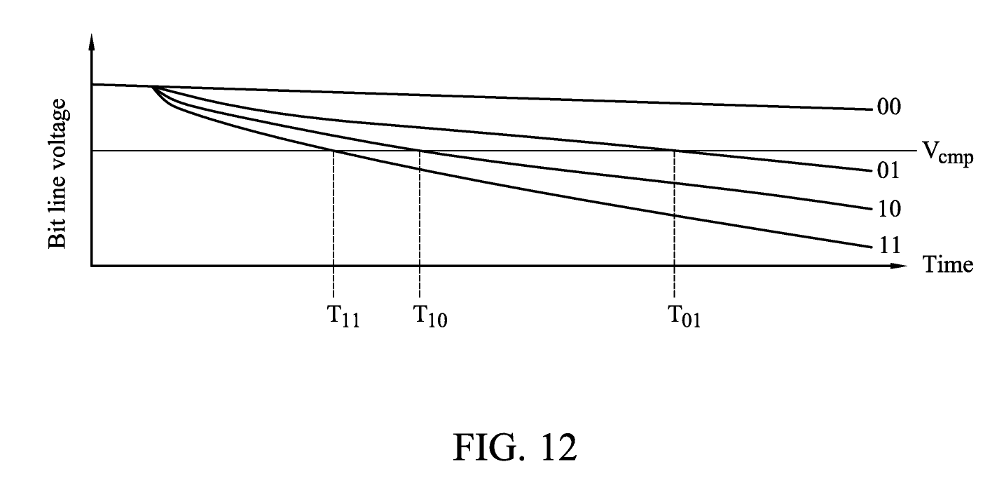

FIG. 12 shows an exemplary discharge curve of four states according to an embodiment of the invention. Under the same gate voltage V_{G}, the memory cell storing data 11 may conduct a large current I_{DS} (see FIG. 11B). Thus, the time T₁₁ required for discharging the bit-line voltage of the memory cell storing data 11 to the reference voltage V_{cmp} is the shortest, one when compared among the memory cells storing four different states 00, 01, 10, 11.

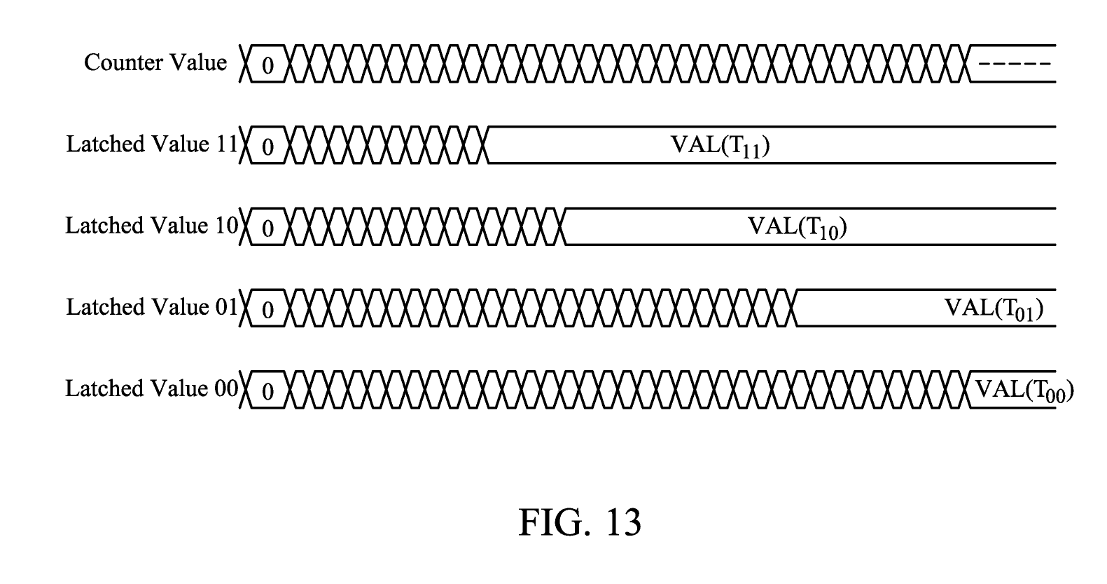

FIG. 13 shows an exemplary counter value and the latched values for four different states according to an embodiment of the invention. As previously described, the latch in each detecting circuit latches a current value counted by the counter when the comparison result indicates that the voltage or conducted current of the memory cell to be read is smaller than the reference voltage or current. Therefore, by differentiating the latched values, the content of data (for example, 00, 01, 10 or 11) stored in the corresponding memory cell may be obtained.

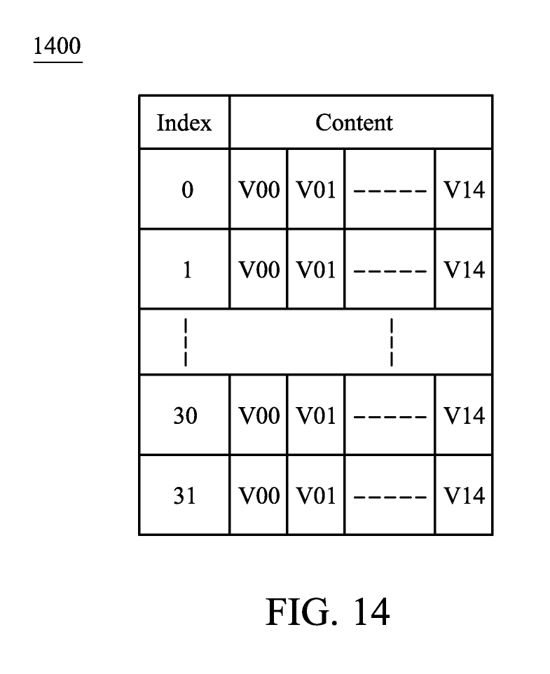

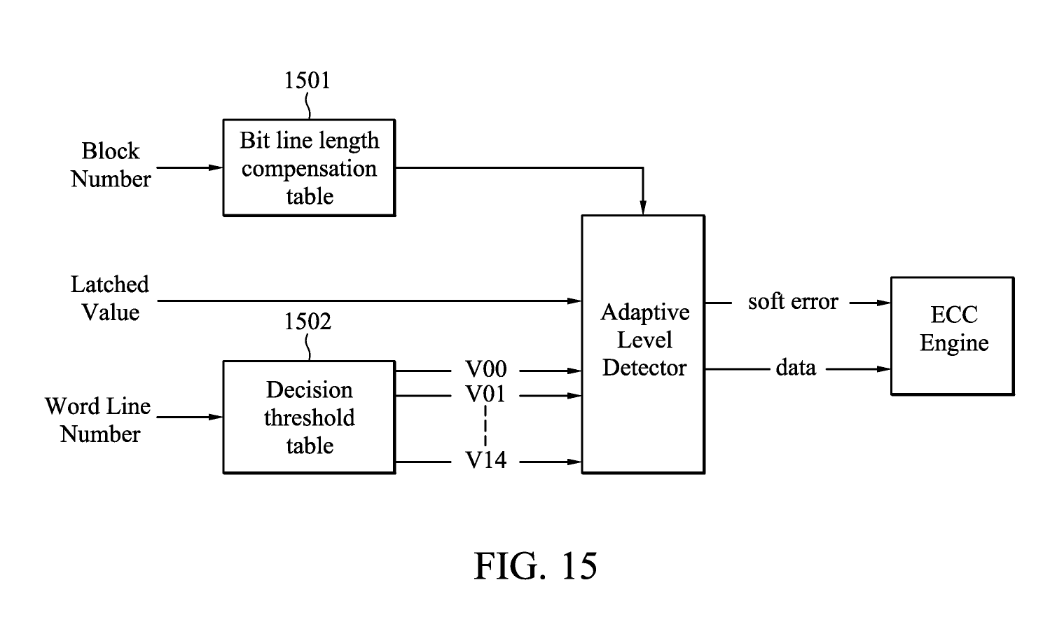

According to the first embodiment of the invention, the detecting circuit may output the latched value as the digital signal, and the adaptive level detector (e.g. 314 or 814) may detect a level of a voltage or conducted current of the memory cell according to the digital signal to obtain the content of the data stored in the memory cell. The adaptive level detector may detect the level of a voltage or conducted current of the memory cell according to a plurality of predetermined decision thresholds. Because the predetermined decision thresholds may vary with different word lines, the adaptive level detector may compensate for the difference between word lines by looking up a decision threshold table that has recorded a plurality of decision thresholds with respect to different word lines. FIG. 14 shows an exemplary decision threshold table according to an embodiment of the invention. The decision threshold table may be indexed by the word line number (or page number) of the memory cell. As shown in the example of FIG. 14, the decision threshold table comprises 32 rows, and each row stores 15 decision thresholds V00 to V14 for the corresponding word line. In this example, each memory cell stores 4 bits of data. Therefore, 15 decision thresholds are required to detect the voltage or current level of each memory cell. Note that the number of word lines and decision thresholds shown here are merely examples and the invention should not be limited thereto.

According to an embodiment of the invention, the decision threshold table may be stored in the memory 313. In addition, in order to compensate for the difference in the bit line length from each memory cell to the detecting point, the adaptive level detector may also look up a bit line length compensation table stored in the memory 313. The bit line length compensation table records compensation values with respect to different bit lines. FIG. 15 shows a method for adaptively generating decision thresholds according to an embodiment of the invention. The adaptive level detector looks up the bit line length compensation table 1501 and the decision threshold table 1502 according to the block number and the word line number (or page number) of the memory cell, respectively, to obtain the decision thresholds and a compensation value. The adaptive level detector further receives the digital signal carrying the latched value and detects the level of the voltage or conducted current of the memory cell according to the decision thresholds, the compensation value and digital signal.

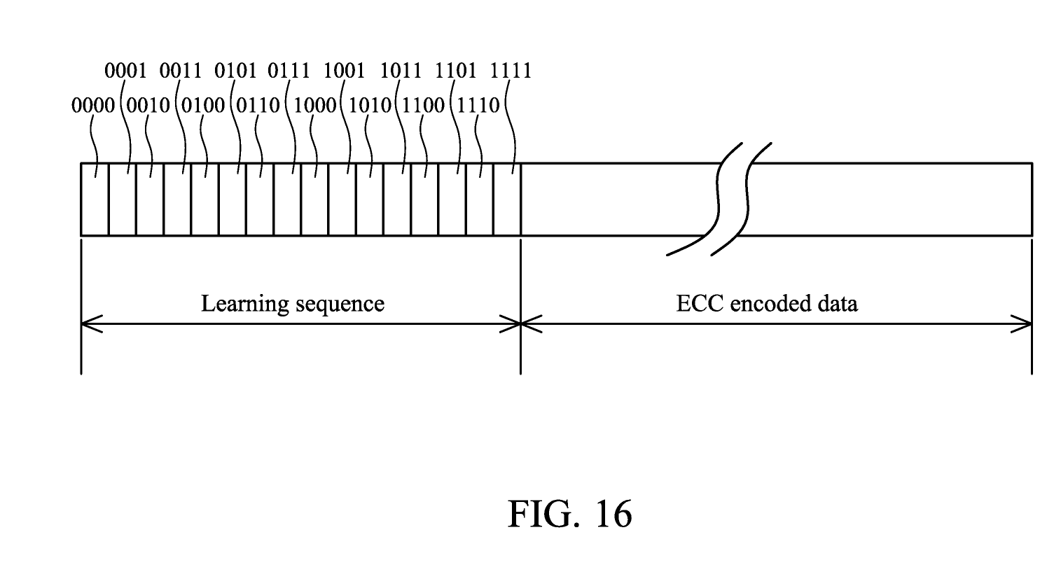

According to an embodiment of the invention, the decision threshold table and the bit line length compensation table may be obtained by detecting the digital signal of a predetermined learning sequence. FIG. 16 shows an exemplary page data according to the embodiment of the invention. The page data comprises a learning sequence with 16 4-bit predetermined data. Note that the learning sequence may be repeated several times to obtain more accurate decision thresholds and compensation values. In addition, the decision threshold table and the bit line length compensation table may also be updated according to the data stored in the memory device after ECC decoding and error correction.

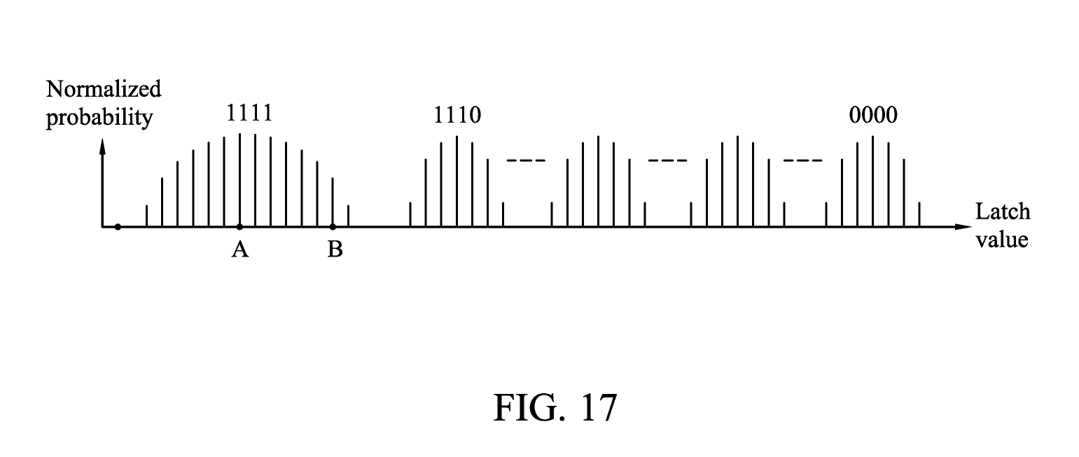

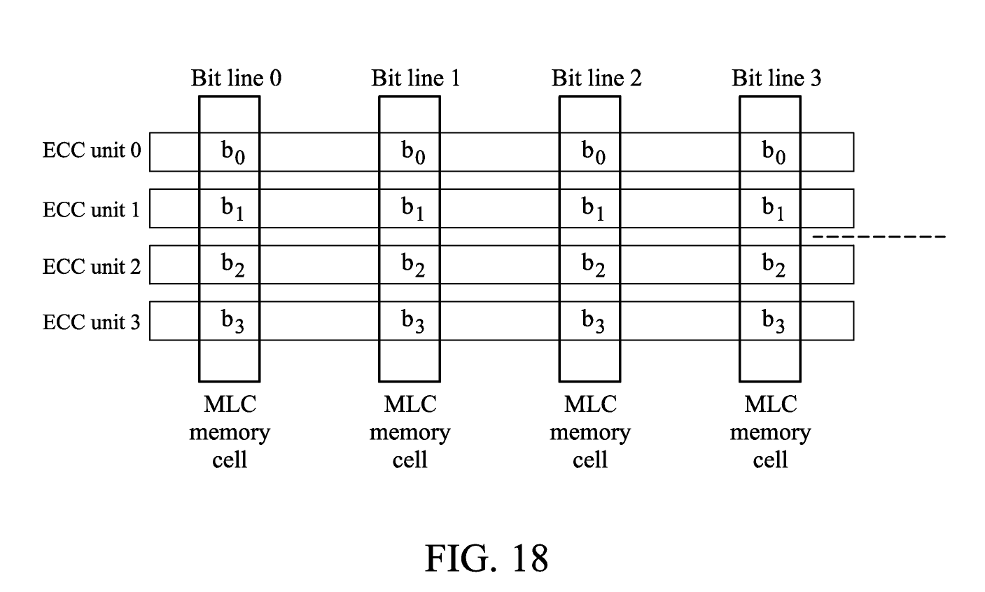

According to an embodiment of the invention, the controller may further generate a histogram for calculating a distribution of different values of the digital signal for different word lines, and dynamically update the decision threshold table according to the histogram. FIG. 17 shows an exemplary histogram for calculating a distribution of the latched values of a dedicated word line according to an embodiment of the invention. According to the histogram, the decision thresholds that are used to differentiate different content stored in the memory cell may be obtained. In addition, a normalized probability of the latched value carried in a digital signal being the obtained content may also be obtained by looking up the histogram. An example as shown in FIG. 17, when the latched value is A, the probability of the latched value A being the logical 1111 is 50%, and when the latched value is B, the probability of the latched value B being the logical 1111 is 10%. The probability of the latched value may be provided by the adaptive level detector as a soft error to the ECC engine for further ECC decoding.

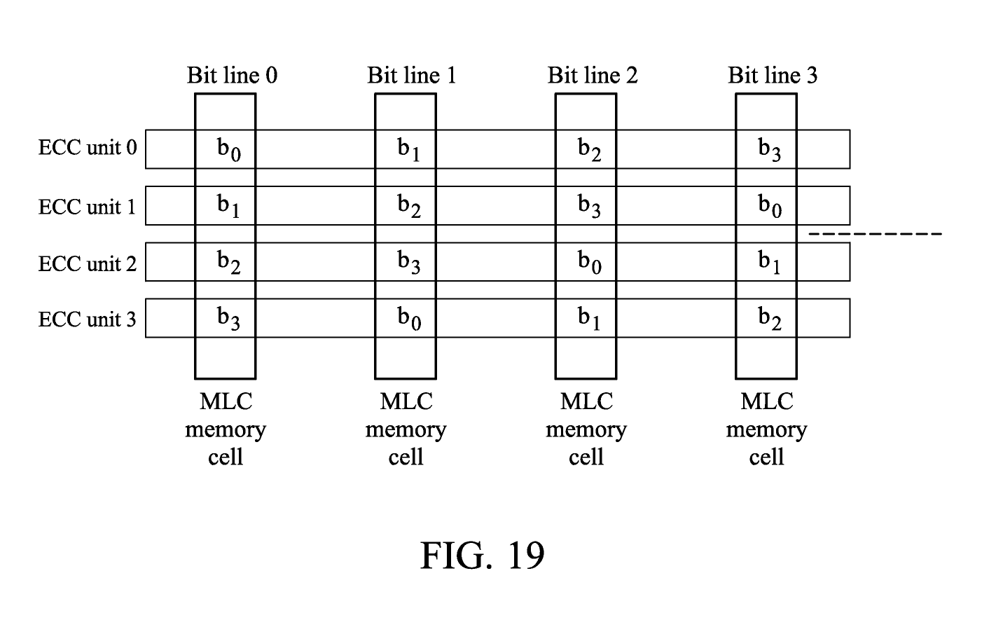

In order to further improve the ECC ability when access multiple bits at the same time, a novel ECC structure is also proposed. According to the embodiments of the invention, instead of interleaving the multiple bits of an MLC memory cell to different pages as shown in FIG. 5A, the multiple bits of an MLC memory cell is arranged in the same page so as to be accessed at the same time. However, in order to further improve the ECC ability, the multiple bits of the same MLC memory cell are interleaved to the different ECC units comprised in the ECC engine (e.g. 315, 815 or 915). FIG. 18 and FIG. 19 respectively shows two methods for interleaving the multiple bits of the same MLC memory cell to the different ECC units according to an embodiment of the invention. In the embodiments, each MLC memory cell stores 4 bits of data.

As shown in FIG. 18, when a Gray Code mapping as shown in FIG. 6 is applied to the data bits b₀ to b₃ of the MLC memory cell, the multiple bits interleaving may be performed by passing the first bit b₀ to the first ECC unit 0, passing the second bit b₁ to the second ECC unit 1, . . . and so on. Meanwhile, when the gray code mapping is not applied, the multiple bits interleaving may be performed as shown in FIG. 19 by passing the first bit b₀ of the first MLC memory cell, the second bit b₁ of the second MLC memory cell, the third bit b₂ of the third MLC memory cell and the fourth bit b₃ of the fourth MLC memory cell to the first ECC unit 0, and passing the second bit b₁ of the first MLC memory cell, the third bit b₂ of the second MLC memory cell, the fourth bit b₃ of the third MLC memory and the first bit b₀ of the fourth MLC memory cell to the second ECC unit 1 . . . and so on. Note that a 4 bit MLC memory cell is used here for illustrating the interleaving concept in a simpler manner. Those who are skilled in this technology can still make various alterations and modifications without departing from the scope and spirit of this invention. Thus, the invention should not be limited thereto.

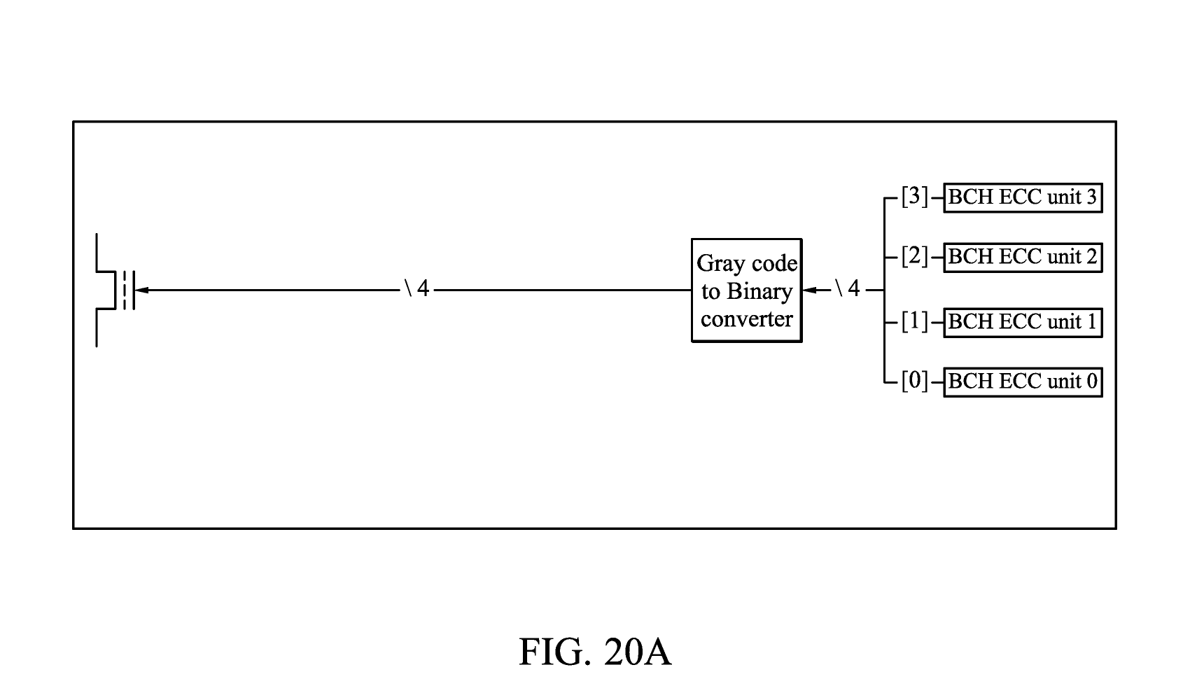

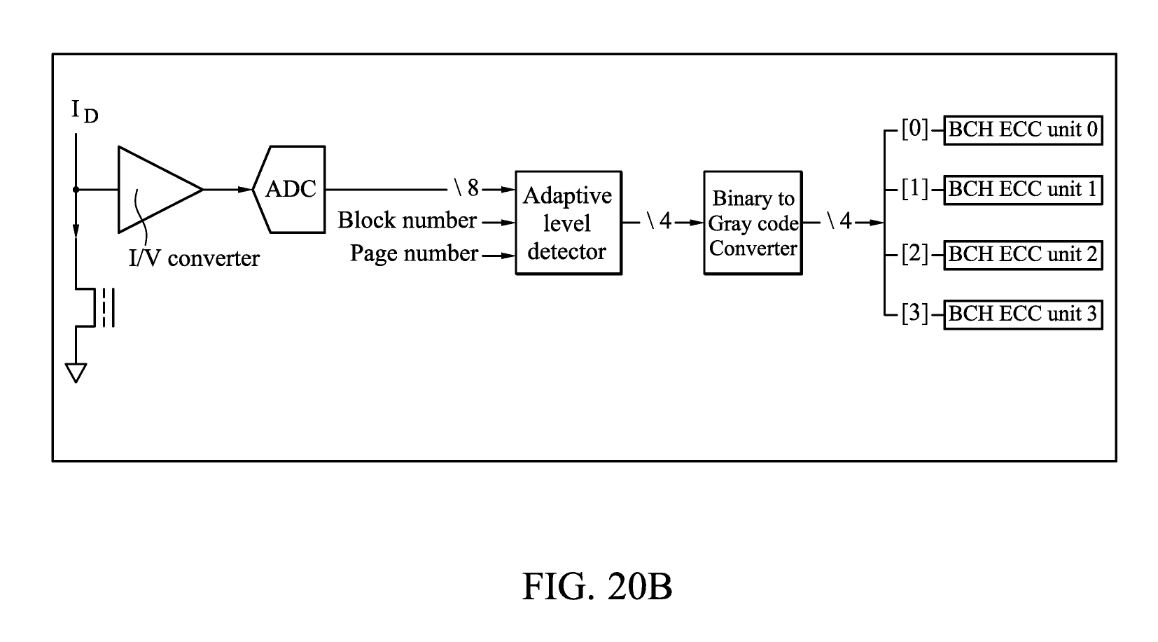

According to the embodiments of the invention, the ECC engines (e.g. 315, 815 or 915) may apply several kinds of different coding schemes. FIG. 20A shows a schematic encoding block diagram applying a Bose, Ray-Chaudhuri and Hocquenghem (BCH) code with a Gray code. FIG. 20B shows a schematic decoding block diagram applying a BCH code with a Gray code. In the embodiment of the invention, the ECC units are BCH ECC units applying a BCH coding scheme. BCH codes were invented in 1959 by Hocquenghem, and independently in 1960 by Bose and Ray-Chaudhuri. The principal advantage of BCH codes is the ease with which they can be decoded, via an elegant algebraic method known as syndrome decoding. According to the embodiments of the invention, as shown in FIG. 20A, after the data is BCH encoded by the BCH ECC units and Gray Code for binary conversion, the data is programmed to the memory cell. When reading the data from the memory device, a reverse process is performed, wherein the data is first binary converted to a Gray Code and the decoded BCH decoded.

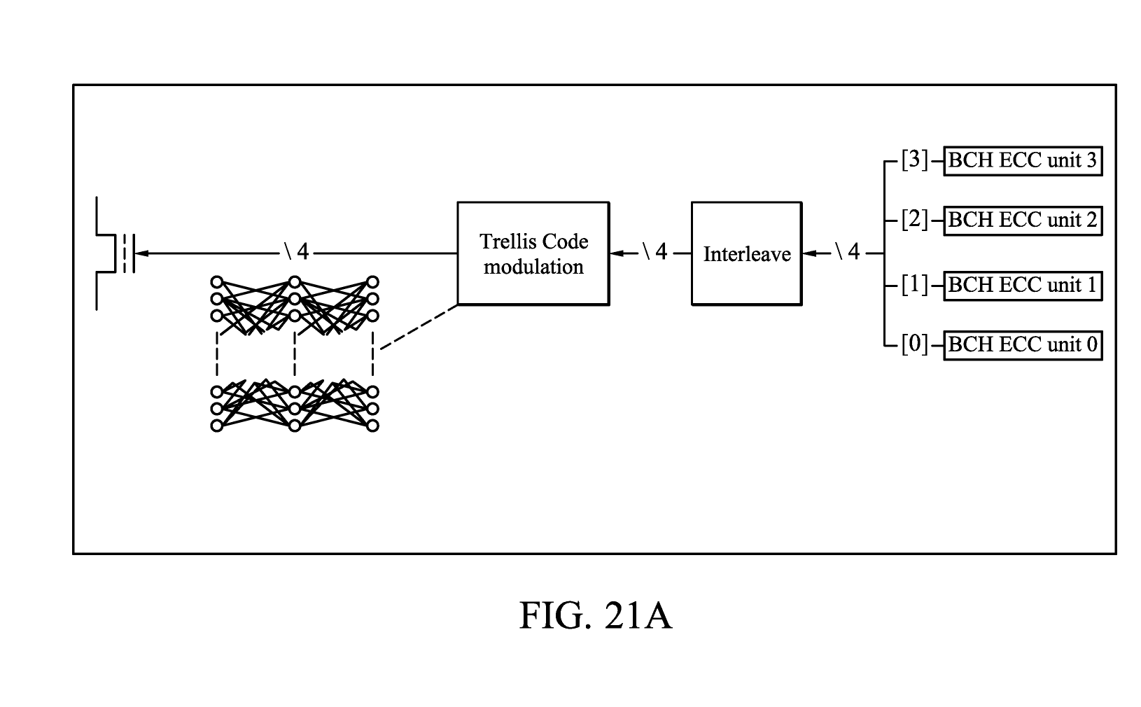

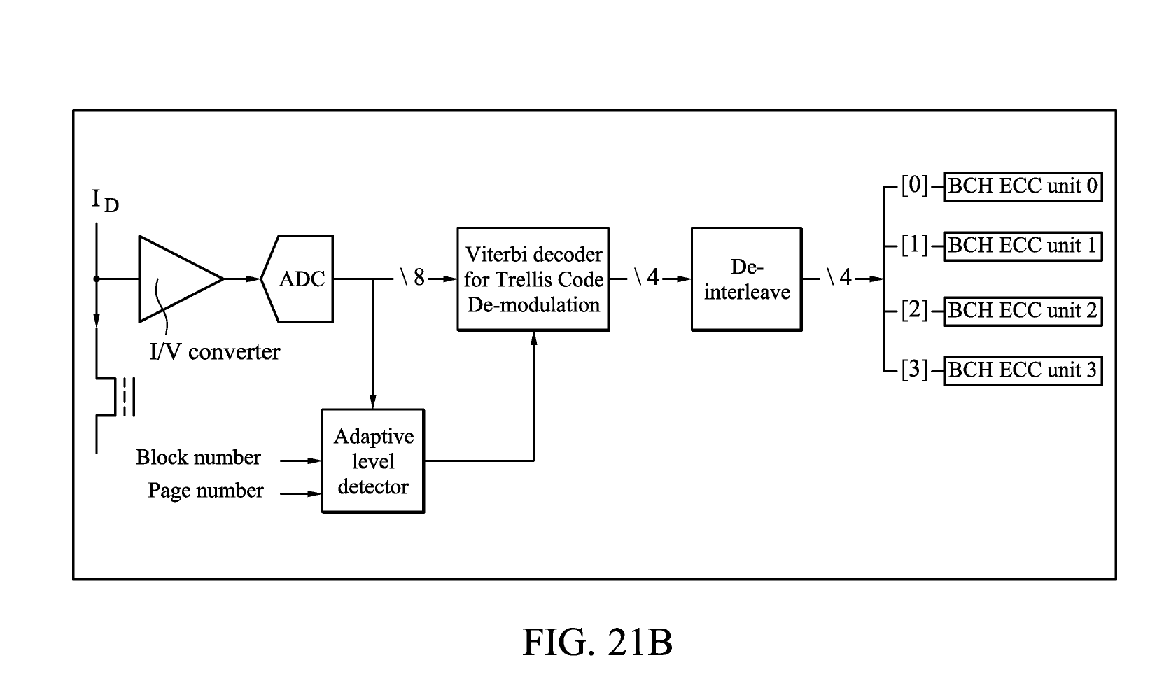

FIG. 21A shows a schematic encoding block diagram applying a BCH code with Trellis Coded Modulation (TCM) according to another embodiment of the invention and FIG. 21B shows a schematic decoding block diagram applying a BCH code with TCM. Trellis Code demodulation invented by Gottfried Ungerboeck is a modulation scheme used in telecommunication, and the Viterbi decoding algorithm invented by Andrew Viterbi is used to decode TCM in the embodiments of the invention. According to the embodiments of the invention, as shown in FIG. 21A, after the data is BCH encoded by the BCH ECC units, the data is interleaved, Trellis Code modulated and then programmed to the memory cell. When reading the data from the memory device, the level detected by the adaptive level detector is output to the Viterbi Decoder for Trellis Code demodulation. The demodulation results are de-interleaved and BCH decoded by the BCH ECC units. An advantage of using trellis code modulation is that it can fully utilize each identifiable MLC level when the number of MLC identifiable levels is not an integer to the power of 2, such as 19 levels instead of 16 levels.

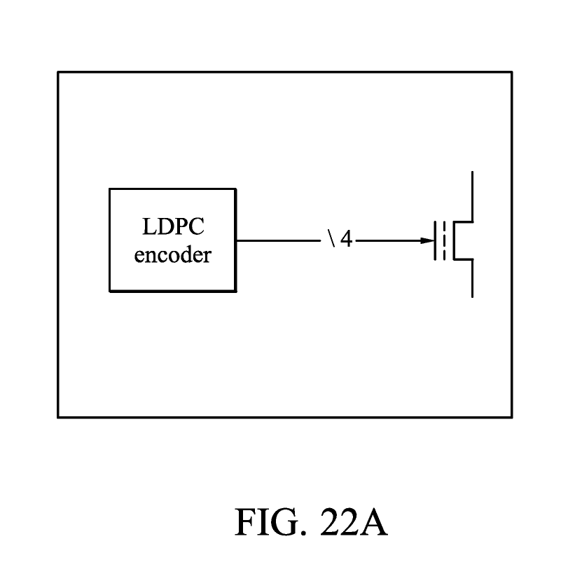

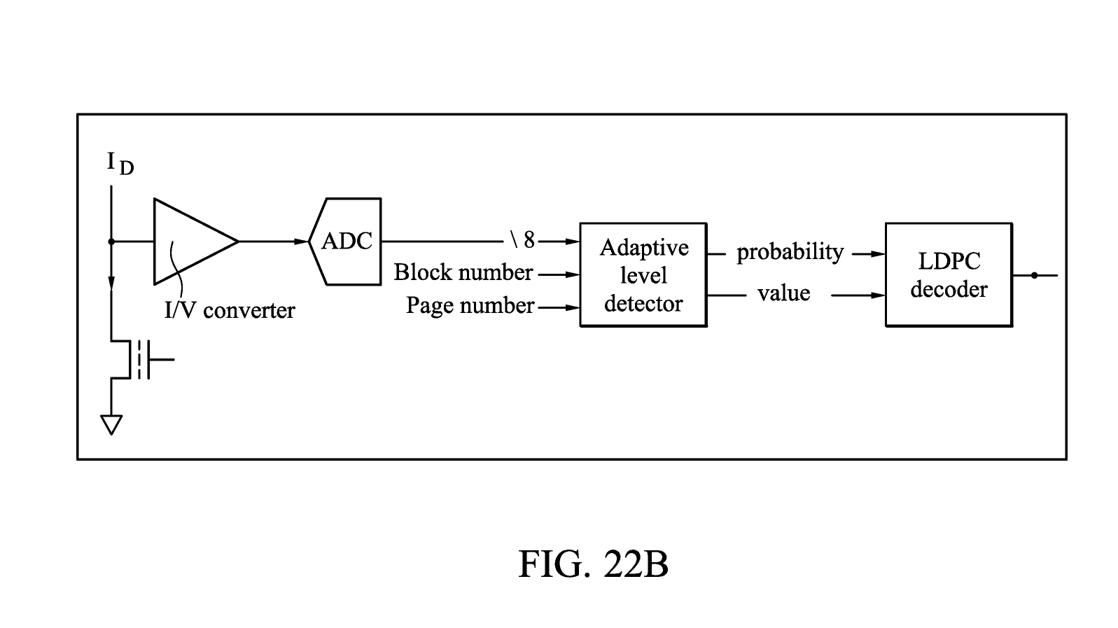

FIG. 22A shows a schematic encoding block diagram applying a Low Density Parity Check code (LDPC code) according to another embodiment of the invention, and FIG. 22B shows a schematic decoding block diagram applying a LDPC code with a soft decision. LDPC is a linear error correcting code used in highly efficient transfer over a noisy channel, such as 10GBase-T Ethernet, and LDPC allow a noise upper bound close to the theoretical maximum to keep the small error probability of information as desired. According to the embodiments of the invention, as shown in FIG. 22A, the data is LDPC encoded before being programmed to the memory cell. When reading the data from the memory device, a value of the level detected by the adaptive level detector and information regarding a difference between the digital signal and the decision thresholds are output to the LDPC decoder for a soft decision. According to an embodiment of the invention, the information may be the probability or probabilities that the latched value (i.e. the digital result) could be one detected level or more different detected levels of the adaptive level detector. When the error checking result indicates that an error has occurred in the decoded data, the probability may be used to correct the error bit to the most possible value. As an example, referring to FIG. 17, when the latched value is B, the adaptive level detector may further determine that the probability of the latched value B being the logical 1111 is 10%, and the probability of the latched value B being the logical 1110 is 5%. The probabilities of the latched value may be provided as the soft error to the LDPC decoder for a soft decision that can improve the capacity of error-correction obviously. When the error checking result determines that an error has occurred, the LDPC decoder may correct the detected level to 1111 because it has the highest probability when compared to 1110.

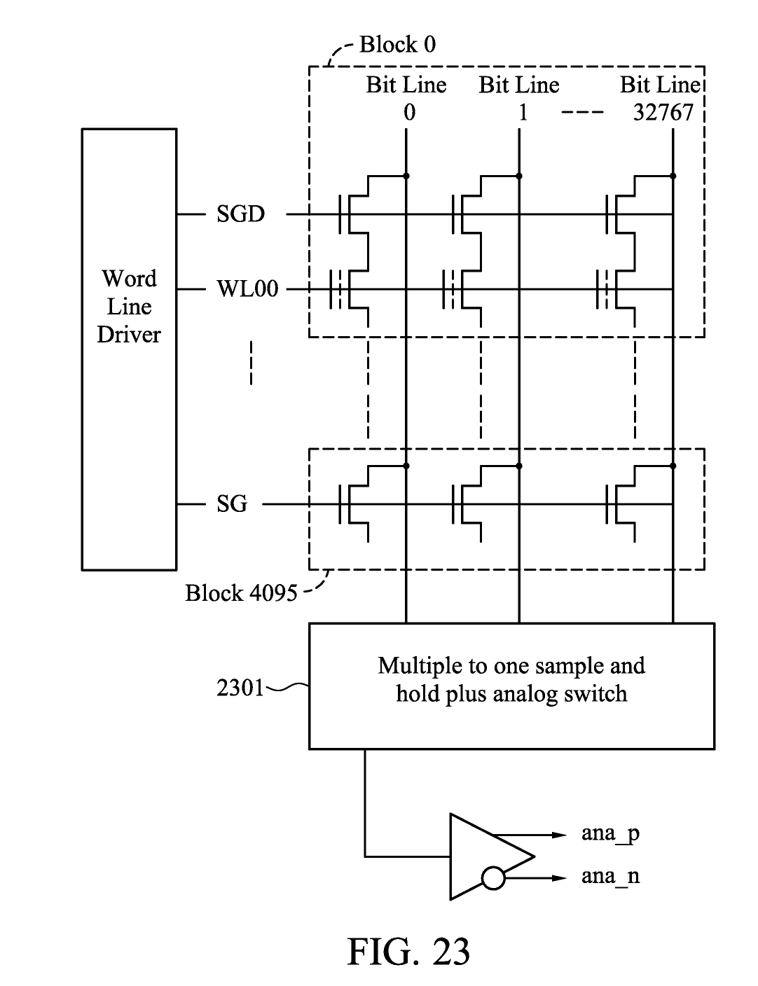

Referring back to FIG. 9, according to the second embodiment of the invention, there may be an analog interface between the memory device 902 and the controller 901. The controller 901 receives the pair of analog and differential detected signals ana_p and ana_n from the memory device 902 and converts the pair of analog and differential detected signals to the digital signal. FIG. 23 shows a detecting circuit 2301 in the memory device according to another embodiment of the invention. According to the second embodiment, the detecting circuit 2301 may be a multiple to one sample and hold plus analog switch. As an example, when the memory device comprises 32768 strings, the detecting circuit 2301 may be a 32768 to 1 sample and hold plus analog switch. The multiple to one sample and hold plus analog switch first detects the threshold voltage or conducted current of the memory cell to be read, and then captures the detected voltage or current. Next, the detected voltage or current is output as a pair of analog and differential detected signals ana_p and ana_n to the controller.

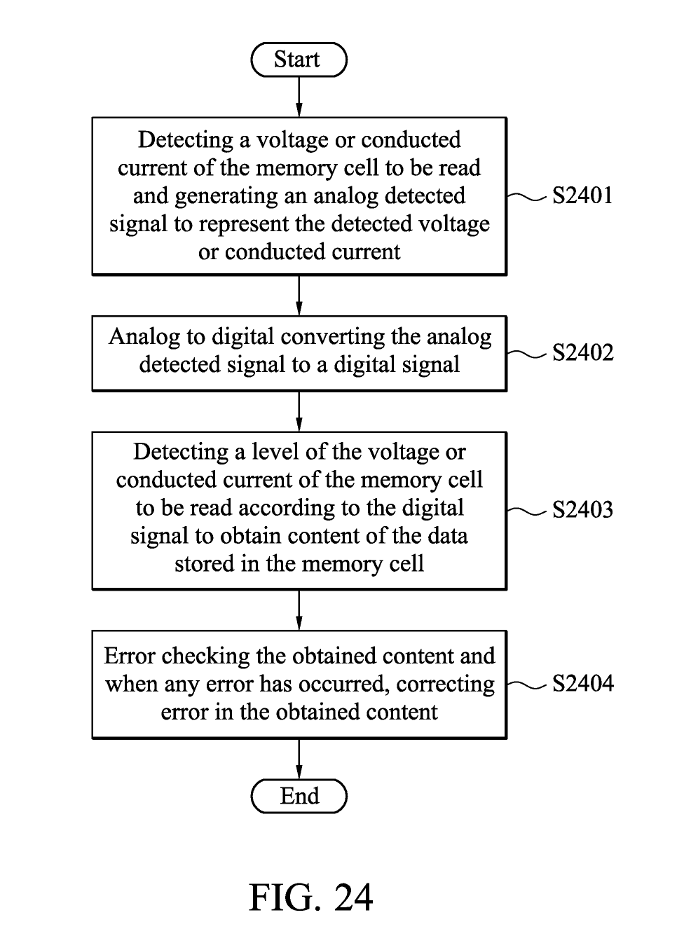

FIG. 24 shows a flow chart of a method for reading data stored in a memory cell in a memory device. When reading data stored in a memory cell, the memory device first detects a voltage or conducted current of the memory cell to be read and generates an analog detected signal to represent the detected voltage or conducted current (Step S2401). According to an embodiment of the invention, the voltage or conducted current of the memory cell may be detected by measuring time required for discharging a bit-line voltage of the memory cell to be read to a reference voltage to obtain a measurement result, and the analog detected signal representing the detected voltage or conducted current of the memory cell to be read may be generated accordingly. Next, the memory device or the controller converts the analog detected signal to a digital signal (Step S2402). Next, the controller detects a level of the voltage or conducted current of the memory cell to be read according to the digital signal to obtain content of the data stored in the memory cell (Step S2403). Finally, the controller checks the obtained content for errors and when it is determined that an error has occurred, corrects the error in the obtained content (Step S2404). According to an embodiment of the invention, a plurality of decision thresholds of the memory cell to be read, which have been stored in a decision threshold table, may be obtained according to a word line number of the memory cell, for detecting the level of the voltage or conducted current of the memory cell to be read. A soft error indicating a probability of the digital signal being the obtained content may further be obtained according to a difference between the digital signal and the decision thresholds. And in the error correction step, the error in the obtained content may be corrected according to the soft error as previously described.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A memory system, comprising:
a memory device, comprising a plurality of memory cells for storing data; and
a controller, coupled to the memory device for accessing the memory device, wherein when reading the data stored in a memory cell, the controller receives a digital signal representing content of the data stored in the memory cell, and detects a level of a voltage or conducted current of the memory cell to obtain the content of the data according to the digital signal.

2. The memory system as claimed in claim 1, wherein the memory device detects the voltage or conducted current of the memory cell to be read and generates an analog detected signal to represent the detected voltage or conducted current, and the memory device further comprises a converter converting the analog detected signal to the digital signal.

3. The memory system as claimed in claim 1, wherein the memory device detects the voltage or conducted current of the memory cell to be read and generates a pair of analog and differential detected signals to represent the detected voltage or conducted current, and the controller further comprises a converter converting the pair of analog and differential detected signals to the digital signal.

4. The memory system as claimed in claim 1, wherein the memory device further comprises:
a plurality of bit lines, coupled in serial fashion;
a plurality of detecting circuits, each coupled to one of the bit lines for detecting the voltage or conducted current of the memory cells; and
a counter, coupled to the detecting circuits;
wherein each of the detecting circuit comprises:
a comparator, comparing the voltage or conducted current of the memory cell to be read with a reference voltage or current; and
a latch, coupled to the counter and an output of the comparator, receiving a comparison result of the comparator and latching a value counted by the counter according to the comparison result,
wherein the digital signal is derived from the value.

5. The memory system as claimed in claim 1, wherein the controller comprises:
an adaptive level detector, detecting the level of the voltage or conducted current of the memory cell to be read for obtaining the content of the data according to the digital signal; and
an error correcting code (ECC) engine, checking the obtained content for errors, and when determining an error has occurred, correcting the error in the obtained content.

6. The memory system as claimed in claim 5, wherein the memory device further comprises a plurality of memory blocks, each memory block comprises a plurality of word lines, and each word line is coupled to the memory cells, and wherein the controller further comprises:
a memory, storing a decision threshold table recording a plurality of decision thresholds with respect to different word lines,
wherein the adaptive level detector obtains the decision thresholds according to the decision threshold table and the word line number of the memory cell to be read, respectively, and detects the level of the voltage or conducted current of the memory cell to be read according to the decision thresholds and digital signal.

7. The memory system as claimed in claim 6, wherein the adaptive level detector further provides a soft error indicating a probability of the digital signal being the obtained content to the ECC engine according to a difference between the digital signal and the decision thresholds.

8. The memory system as claimed in claim 1, wherein each of the memory cells stores more than one bit, and the bits corresponding to one memory cell are simultaneously accessed in the read operation.

9. The memory system as claimed in claim 5, wherein the ECC engine comprises a plurality of ECC units and each of the memory cells stores more than one bit, and the bits corresponding to one memory cell are interleaved to the different ECC units.

10. The memory system as claimed in claim 5, wherein the ECC engine comprises a Gray Code to binary converter, a binary to Gray Code converter, and a plurality of Bose, Ray-Chaudhuri and Hocquenghem (BCH) code ECC units.

11. The memory system as claimed in claim 5, wherein the ECC engine comprises a Trellis code modulator, a Viterbi decoder, and a plurality of Bose, Ray-Chaudhuri and Hocquenghem (BCH) code ECC units.

12. The memory system as claimed in claim 5, wherein the ECC engine comprises a Low Density Parity Check (LDPC) code encoder and an LDPC code decoder, and the adaptive level detector further provides information regarding a difference between the digital signal and the decision thresholds.

13. A memory system, comprising:
a memory device, comprising a plurality of memory cells for storing data, and when reading the data stored in a memory cell, detecting a voltage or conducted current of the memory cell to be read and generating an analog detected signal to represent the detected voltage or conducted current; and
a controller, comprising:
a converter, receiving the analog detected signal from the memory device and converting the analog detected signal to a digital signal;
an adaptive level detector, detecting a level of the voltage or conducted current of the memory cell to be read according to the digital signal to obtain the content of the data; and
an error correcting code (ECC) engine, checking the obtained content for errors and when it is determined that an error has occurred, and correcting the error in the obtained content.

14. The memory system as claimed in claim 13, wherein the memory device further comprises a plurality of memory blocks, each memory block comprises a plurality of word lines, and each word line is coupled to the memory cells, and wherein the controller further comprises:
a memory, storing a decision threshold table recording a plurality of decision thresholds with respect to different word lines,
wherein the adaptive level detector obtains the decision thresholds according to the decision threshold table and the word line number of the memory cell to be read, respectively, and detects the level of the voltage or conducted current of the memory cell to be read according to the decision thresholds and digital signal.

15. The memory system as claimed in claim 14, wherein the adaptive level detector further provides a soft error indicating a probability of the digital signal being the obtained content to the ECC engine according to a difference between the digital signal and decision thresholds.

16. The memory system as claimed in claim 13, wherein each of the memory cells stores more than one bit, and the bits corresponding to one memory cell are simultaneously accessed in the read operation.

17. The memory system as claimed in claim 13, wherein the ECC engine comprises a plurality of ECC units and each of the memory cells stores more than one bit, and the bits corresponding to one memory cell are interleaved to the different ECC units.

18. A method for reading data stored in a memory cell of a memory, comprising:
measuring time required for discharging a bit-line voltage of the memory cell to a reference voltage to obtain a measurement result;
generating an analog detected signal to represent a detected voltage or conducted current of the memory cell according to the measurement result;
converting the analog detected signal to a digital signal; and
detecting a level of the voltage or conducted current of the memory cell according to the digital signal to obtain content of the data stored in the memory cell.

19. The method as claimed in claim 18, wherein the measuring step further comprises:
counting a value by using a counter;
comparing a voltage of the memory cell with the reference voltage to obtain a comparison result; and
latching the value when the comparison result indicates that the voltage of the memory cell becomes smaller than the reference voltage.

20. The method as claimed in claim 18, further comprising:
obtaining a plurality of decision thresholds of the memory cell according to a word line number of the memory cell, wherein the level of the voltage or conducted current of the memory cell is detected according to the decision thresholds and digital signal;
obtaining a soft error indicating a probability of the digital signal being the obtained content according to a difference between the digital signal and the decision thresholds; and
checking the obtained content for errors, and correcting the error in the obtained content according to the soft error when an error has occurred.
